(19) United States
(12) Patent Application Publication
(10) Pub. No.: US 2015/0130475 A1
(43) Pub. Date: May 14, 2015

(54) Street light cable anti-theft system

(71) Applicant: Heifei Zhang, Shanghai (CN)

(72) Inventor: Heifei Zhang, Shanghai (CN)

(21) Appl. No.: 13/993,270

(22) PCT Filed: Sep. 22, 2012
(86) PCT No.: PCT/CN2012/081790

§ 371 Date: Jun. 11, 2013

(30) Foreign Application Priority Data
May 17, 2012 (CN) 201210153864.8

(51) Int. Cl. G01R 31/02; G08B 13/22

(52) U.S. Cl. CPC G01R 31/025; G01R 31/021; G08B 13/22
USPC 324/511

(57) ABSTRACT

A street light cable anti-theft system includes a front-end control device, a signal control device and an information processing terminal. The front-end control device is disposed within a street light control box for applying a voltage signal to a street light cable when a street light is switched off. The signal control device is installed on a lighting pole of a last street light of a public lighting circuit for detecting a voltage signal of the street light cable, determining a state of the street light cable based on the obtained voltage signal, and sending the state signal to the information processing terminal. The information processing terminal is adapted for receiving and processing the state signal sent by the signal control device. The anti-theft system has some advantages of timely obtaining the information of the cable, low maintenance cost, not being affected by power failure and high reliability.

### BACKGROUND OF THE PRESENT INVENTION

1. Field of Invention

The present invention relates to a street light cable anti-theft system, and more particularly to a street light cable anti-theft system which is capable of monitoring the power supply cable by monitoring whether the short circuit or the open circuit of the cable occurs.

2. Description of Related Arts

Presently, the cable cores of the street lamp lighting circuit and the low-voltage power supply circuit are mostly made of metal such as aluminum and copper. Moreover, many circuits are arranged outdoors. Therefore, some lawbreakers have the chances to steal the cables. The stolen phenomena of the cables are increasingly serious. These lawbreakers often steal the cables after midnight, and here, the street lights are turned off, the power of the cables is cut and the pedestrians are few. Once the street light cables are stolen, not only the property of the country and the people are lost, but also the normal lighting of the street lights are affected, thereby bringing a lot of inconveniences to the life of the people and affecting the normal life order. Therefore, some measures are needed to prevent the cables being stolen. The commonly method is that one end or two ends of the cable are fixed within the concrete base of the street light. The shortcomings of this method are described as below. In the later cable maintenance work, more work and greater expenditure are needed, and the maintenance cost is high. In addition, in the method mentioned above, if the cable is destroyed, it is hard for the manager to find this situation at the first time, which goes against the timely processing of the accident.

### SUMMARY OF THE PRESENT INVENTION

An object of the present invention is to provide a street light cable anti-theft system which is capable of making the worker obtain the information that whether the street light cable is destroyed and the situation where the cable is destroyed at any moment, thereby reducing the maintenance cost.

Accordingly, in order to accomplish the above object, the present invention provides a street light cable anti-theft system, comprising a front-end control device, a signal control device and an information processing terminal, wherein the front-end control device is disposed within a street light control box for applying a voltage signal to a street light cable when the street light EL is turned off, the signal control device is installed on a lighting pole of a last street light EL of a public lighting circuit for detecting a voltage signal of the street light cable, based on the obtained voltage signal, a state of the cable is determined, and the state signal is sent to the information processing terminal by a wireless communication network, the front-end control device is connected with the signal control device by the street light cable, the street light EL is connected with the street light cable, and the information processing terminal is adapted for receiving and processing the state signal sent by the signal control device.

Preferably, the front-end control device comprises two contactors, a battery pack GB1 and a switch controller K, wherein the contactor KM1 is adapted for controlling the switch-on/off of the street light cable, the battery pack GB1 is charged by a charger EC which is connected with an alternating current (AC) or solar cells, for applying a 12V direct current (DC) voltage to the cable by the contactor KM2, and the switch controller K is adapted for controlling the switch-on/off of the contactor KM1 and the contactor KM2.

Preferably, a positive electrode of the battery pack GB1 is connected with a fuse FU2 which is adapted for protecting the battery pack GB1 when a short circuit occurs.

Preferably, the switch controller K is a time controller or a street light terminal controller.

Preferably, the signal control device comprises a voltage detector VM, a signal transmission device, a battery pack GB2 and a rectifier filter circuit comprising a bridge rectifier V and a capacitor C, wherein the rectifier filter circuit is adapted for rectifying and filtering the voltage signal applying to the street light cable, the voltage detector VM is adapted for detecting the output voltage of the rectifier filter circuit, judging the state of the cable according to the output voltage, transforming the state of the cable into a switch signal, and sending the switch signal to the signal transmission device, the signal transmission device is adapted for continuously detecting the switch signal of the voltage detector VM to determine whether the alarm signal is sent by the wireless communication network, the voltage detector VM and the signal transmission device are powered by the battery pack GB2, and the battery pack GB2 is charged by the charger EC which is connected with an alternating current or solar cells.

Preferably, the signal transmission device is a Global System for Mobile communication (GSM) signal transmission device.

Preferably, a positive electrode of the battery pack GB2 is connected with a fuse FU3 which is adapted for protecting the battery pack GB2 when a short circuit occurs.

Preferably, the street light EL is connected with the street light cable by a ballast B.

Compared with the prior art, the street light cable anti-theft system of the present invention has some beneficial effects as follow.

1. The street light cable anti-theft system of the present invention can provide the real-time monitoring for the state of the cable. When the cable is stolen or the short-circuit fault of the cable occurs, it can rapidly and timely inform the manager, thereby minimizing the loss. However, for the conventional anti-theft and anti-destroy methods, the manger can find that the cables are stolen after a long time.

2. The street light cable anti-theft system of the present invention has the simple structure, low failure rate, and low maintenance cost.

3. Even if the power cut of the system occurs, due to the backup power, the street light cable anti-theft system of the present invention still can work for a long time. When the battery is charged by the solar cells, the effects on the system caused by the power cut can be ignored.

4. The street light cable anti-theft system of the present invention can use the GSM network to send the alarm signal, and can sent the information that the cable is stolen to the information processing terminal such as the designated mobile phone or computer by the GSM network, such that the manger can know the information that the cable is destroyed at the first time, thereby obtaining the high reliability.

The street light cable anti-theft system of the present invention has some advantages of timely obtaining the information of the cable, low maintenance cost, not being affected by power failure or power cut, and high reliability.

The street light cable anti-theft system of the present invention can be applied to monitor not only the street light cables of the municipal administration, but also other low-voltage power supply cables.

These and other objectives, features, and advantages of the present invention will become apparent from the following detailed description, the accompanying drawings, and the appended claims.

### BRIEF DESCRIPTION OF THE DRAWINGS

FIG. 1 is a schematic diagram of a street light cable anti-theft system according to a preferred embodiment of the present invention.

FIG. 2 is a block diagram of the street light cable anti-theft system according to the above preferred embodiment of the present invention.

In the drawings, 1: front-end control device; 2: signal control device; 3: information processing terminal; 4: street light cable; B: ballast; C: capacitor; FU1: fuse; FU2: fuse; FU3: fuse; GB1: battery pack; GB2: battery pack; GSM: GSM signal transmission device; K: switch controller; KM1: contactor; KM2: contactor; EL: street light; V: bridge rectifier; VM: voltage detector; L: live wire; N: zero wire; S1: signal detection terminal; S2: signal detection terminal; O1: output terminal of the switch signal; O2: output terminal of the switch signal; I1: signal input terminal; and I2: signal input terminal.

### DETAILED DESCRIPTION OF THE PREFERRED EMBODIMENT

The present invention is further explained in detail with the accompanying drawings.

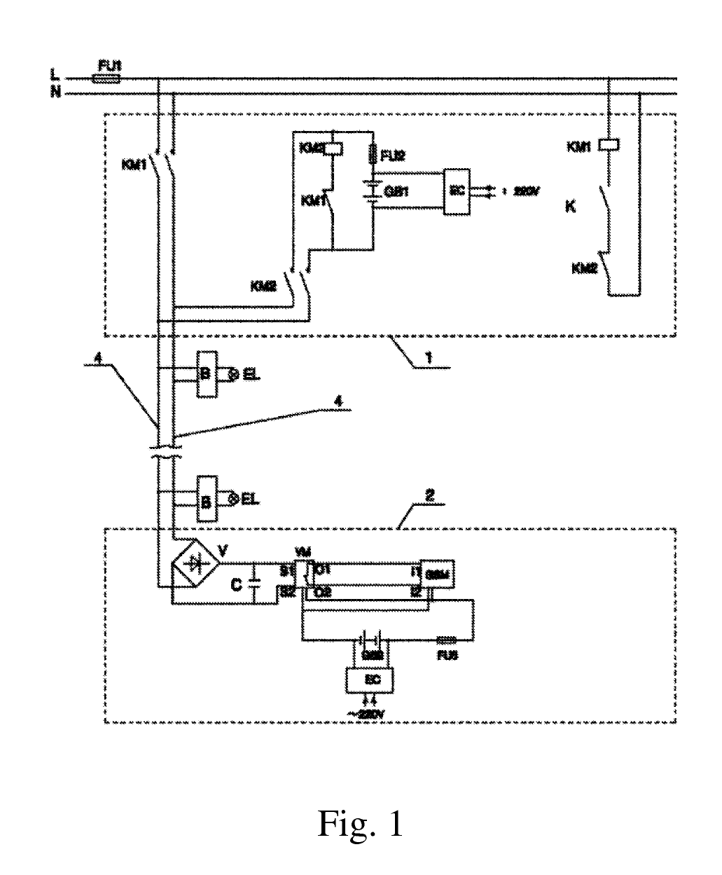

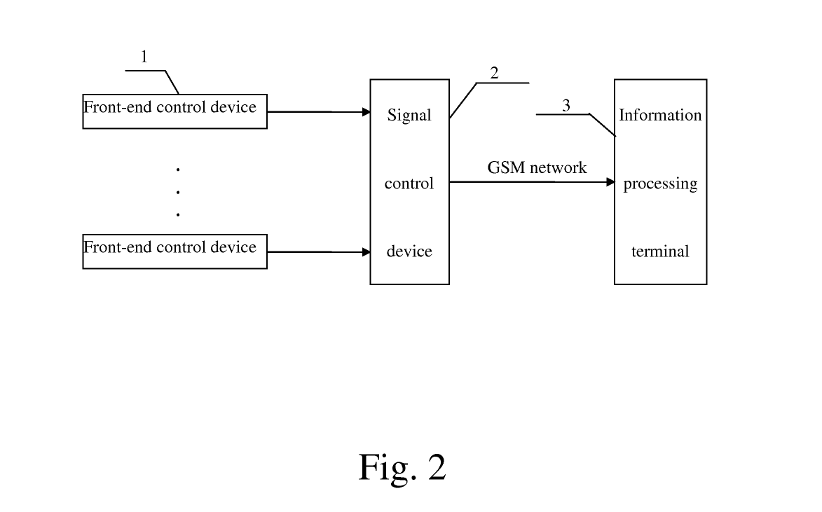

Referring to FIGS. 1 and 2 of the drawings, a street light cable anti-theft system according to a preferred embodiment of the present invention is illustrated, wherein the street light cable anti-theft system comprises a front-end control device 1, a signal control device 2 and an information processing terminal 3. The front-end control device 1 is disposed within the street light control box for applying a voltage signal to the street light cable 4 when the street light EL is turned off. The signal control device 2 is installed on the lighting pole of the last street light EL of a public lighting circuit for detecting the voltage signal of the street light cable 4. Based on the obtained voltage signal, the state of the cable 4 is determined, and the state signal is sent to the information processing terminal 3 by the wireless communication network. When the street light is turned on, the 220V alternating current (AC) voltage is applied to the street light cable by the municipal power supply system. When the street light is turned off, the 12V direct current (DC) voltage is applied to the street light cable by the battery pack GB1. The front-end control device 1 is connected with the signal control device 2 by the street light cable 4. The street light EL is connected with the street light cable 4. The information processing terminal 3 is adapted for receiving and processing the state signal sent by the signal control device 2. The front-end control device 1 comprises two contactors, a battery pack GB1 and a switch controller K. The contactor KM1 is adapted for controlling the switch-on/off of the street light cable 4. The battery pack GB1 is charged by the charger EC which is connected with the alternating current or solar cells, for applying a 12V direct current (DC) voltage to the cable 4 by the contactor KM2. The contactor KM1 and the contactor KM2 are interlocked with each other by their own normally closed contacts. The switch controller K is adapted for controlling the switch-on/off of the contactor KM1 and the contactor KM2. The positive electrode of the battery pack GB1 is connected with the fuse FU2 which is adapted for protecting the battery pack GB1 when a short circuit occurs. The switch controller K is a time controller or a street light terminal controller. The time controller controls the switch-on of the street light by time and luminosity, namely, by setting the time, the street light is turned on at night or turned off during the day, or by controlling the luminosity, the street light is turned on when the weather is gloomy and the brightness of the sun is too low. In practice, the street light is turned on or off by combining the time control with the luminosity control. The street light terminal controller is a wireless remote control terminal and is capable of controlling the switch-on/off of the street light by the wireless network. The signal control device 2 comprises a voltage detector VM, a signal transmission device, a battery pack GB2 and a rectifier filter circuit comprising the bridge rectifier V and the capacitor C. The rectifier filter circuit is adapted for rectifying and filtering the voltage signal applying to the street light cable 4. The voltage detector VM is adapted for detecting the output voltage of the rectifier filter circuit, judging the state of the cable 4 according to the output voltage, transforming the state of the cable into a switch signal, and sending the switch signal to the signal transmission device. The voltage detector VM has a plurality of output voltage change ranges and a plurality of output voltage change duration ranges set within.

The output voltage change ranges comprise a first output voltage change range, a second output voltage change range, a third output voltage change range and a fourth output voltage change range. The first output voltage change range is an output voltage deviation produced when the street light EL is at a work condition. The second output voltage change range is an output voltage deviation produced when the street light EL is at a rest condition. The third output voltage change range is an output deviation range produced when the street light EL switches from the work condition to the rest condition. The fourth output voltage change range is an output voltage deviation produced when the street light EL switches from the rest condition to the work condition.

The output voltage change duration ranges comprise a first output voltage change duration range, a second output voltage change duration range, a third output voltage change duration range and a fourth output voltage change duration range. The first output voltage change duration range is a length of time of the output voltage deviation produced when the street light EL is at a work condition. The second output voltage change duration range is a length of time of the output voltage deviation produced when the street light EL is at a rest condition. The third output voltage change duration range is a length of time of the output voltage deviation produced when the street light EL switches from the work condition to the rest condition. The fourth output voltage change duration range is a length of time of the output voltage deviation produced when the street light EL switches from the rest condition to the work condition.

An abnormal state of the cable is judged when an output voltage changes beyond the first output voltage change range and beyond the first output voltage change duration range or when the output voltage changes beyond the second output voltage change range and beyond the second output voltage change duration range or when the output voltage changes beyond the third output voltage change range and beyond the third output voltage change duration range or when the output voltage changes beyond the fourth output voltage change range and beyond the fourth output voltage change duration range.

A normal state of the cable is judged when an output voltage doesn't change beyond the first output voltage change range or doesn't change beyond the first output voltage change duration range or when the output voltage doesn't change beyond the second output voltage change range or doesn't change beyond the second output voltage change duration range or when the output voltage doesn't change beyond the third output voltage change range or doesn't change beyond the third output voltage change duration range or when the output voltage doesn't change beyond the fourth output voltage change range or doesn't change beyond the fourth output voltage change duration range.

The signal transmission device is adapted for continuously detecting the switch signal of the voltage detector VM to determine whether the alarm signal is sent by the wireless communication network. The voltage detector VM and the signal transmission device are powered by the battery pack GB2. The battery pack GB2 is charged by the charger EC which is connected with an alternating current or solar cells. Preferably, the signal transmission device is the Global System for Mobile communication (GSM) signal transmission device. The GSM signal transmission device sends the signal to the information processing terminal 3 of the present system by the GSM communication network of the mobile communication company. The positive electrode of the battery pack GB2 is connected with the fuse FU3 which is used to protect the battery pack GB2 when the short circuit occurs. The street light EL is connected with the cable 4 by a ballast B.

Referring to FIG. 1, in this preferred embodiment of the present invention, the street light is controlled by the switch controller K (time controller or street light terminal controller). At night, according to the set time or photometric parameters, the time controller K (or the street light terminal controller) is closed, the coil of the contactor KM1 is powered, the contactor KM1 is picked up, and the street light is turned on. Here, in the signal control device, the output end of the rectifier filter circuit comprising the bridge rectifier V and the capacitor C produces the relatively stable DC voltage signal, the voltage detector VM detects the voltage signal, transforms the voltage signal into the switch signal and sends the switch signal to the GSM signal transmission device. By detecting the switch signal, the GSM signal transmission device judges whether the cable is abnormal, thereby judging whether the alarm signal is sent to the information processing terminal. The information processing terminal can be a microcomputer for receiving and processing the information, and also can be a mobile telephone. After receiving the alarm signal, the information processing terminal sends the sound signal or optical signal for reminding the worker, and providing the position where the cable fault occurs so that the worker timely handles the fault.

When the street light does not need to work, the switch controller K (time controller or street light terminal controller) is disconnected, the coil of the contactor KM1 is not powered, and the main contact of the contactor KM1 is disconnected. Here, the normally closed contact of KM1 is closed, the coil of the contactor KM2 is powered, the main contact of the contactor KM2 is picked up, and the battery pack GB1 provides a 12V DC signal for the street light cable. Because the DC 12V voltage is not enough to trigger the street light to work, the street light does not light and also does not consume the power. At the switching moment of the contactor KM1 and the contactor KM2, the capacitor C provides the voltage signal for the voltage detector VM, such that the voltage detector VM does not wrongly report at the switching moment. Here, in the signal control device, the output end of the rectifier filter circuit comprising the bridge rectifier V and the capacitor C also produces the relatively stable DC voltage signal, the voltage detector VM detects the voltage signal, transforms the voltage signal into the switch signal and sends the switch signal to the GSM signal transmission device for determining whether the cable is abnormal.

Referring to FIGS. 1, S1 and S2 are signal detection terminals, O1 and O2 are output terminals of the switch signal of the voltage detector, and I1 and I2 are signal input terminals of the signal transmission device. L is the live wire of the municipal power supply system, and N is the zero line of the municipal power supply system.

As shown in FIG. 1, the battery packs GB1 and GB2 in use are charged by the charger EC. The charger EC can be connected with the alternating current or solar cells. The battery packs are charged by the alternating current or solar cells via the charger for ensuring the normal operation of the system while the power failure occurs. The fuses FU2 and FU3 provide the short circuit protection for the battery packs GB1 and GB2, respectively.

The street light cable anti-theft system of the present invention can provide the real-time monitoring for the state of the cable. When the theft or the short circuit fault occurs, the street light cable anti-theft system of the present invention can rapidly and timely inform the manager, thereby minimizing the loss. The street light cable anti-theft system of the present invention has the simple structure, low failure rate and low maintenance cost. Even if the power cut of the system occurs, due to the backup power, the street light cable anti-theft system of the present invention still can work for a long time. If the battery is charged by the solar cells, the effects on the system caused by the power cut can be ignored. The street light cable anti-theft system of the present invention can use the GSM network to send the alarm signal, and can sent the information that the cable is stolen to the information processing terminal such as the designated mobile phone or computer by the GSM network, such that the manger can obtain the information that the cable is destroyed at the first time, thereby obtaining the high reliability. The street light cable anti-theft system of the present invention has some advantages of timely obtaining the information of the cable, low maintenance cost, not being affected by power failure or power cut, and high reliability.

The street light cable anti-theft system of the present invention can be applied to monitor not only the street light cables of the municipal administration, but also other low-voltage power supply cables.

One skilled in the art will understand that the embodiment of the present invention as shown in the drawings and described above is exemplary only and not intended to be limiting.

It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A street light cable anti-theft system, comprising:
a front-end control device disposed within a street light control box for applying a voltage signal to a street light cable when a street light is switched off;
a signal control device installed on a lighting pole of a last street light of a public lighting circuit for detecting a voltage signal of the street light cable, determining a state of the street light cable based on the obtained voltage signal, and sending the state signal to the information processing terminal by a wireless communication network, wherein the front-end control device is connected with the signal control device by the street light cable, and the street light is connected with the street light cable; and
an information processing terminal for receiving and processing the state signal sent by the signal control device.

2. The street light cable anti-theft system, as recited in claim 1, wherein the front-end control device comprises a first contactor, a second contactor, a first battery pack and a switch controller, wherein the first contactor is adapted for controlling a switch-on/off of the street light cable, the first battery pack is charged by a charger which is connected with an alternating current or solar cells, for applying a 12V direct current (DC) voltage to the street light cable by the second contactor, and the switch controller is adapted for controlling a switch-on/off of the first contactor and the second contactor.

3. The street light cable anti-theft system, as recited in claim 1, wherein the signal control device comprises a voltage detector, a signal transmission device, a second battery pack and a rectifier filter circuit comprising a bridge rectifier and a capacitor, wherein the rectifier filter circuit is adapted for rectifying and filtering the voltage signal applying to the street light cable, the voltage detector is adapted for detecting an output voltage of the rectifier filter circuit, judging the state of the street light cable according to the output voltage, transforming the state of the street light cable into a switch signal, and sending the switch signal to the signal transmission device, the signal transmission device is adapted for continuously detecting the switch signal of the voltage detector for determining whether an alarm signal is sent by the wireless communication network, the voltage detector and the signal transmission device are powered by the second battery pack, and the second battery pack is charged by a charger which is connected with an alternating current or solar cells.

4. The street light cable anti-theft system, as recited in claim 3, wherein the voltage detector VM has a plurality of output voltage change ranges and a plurality of output voltage change duration ranges set within, wherein an abnormal state of the cable is judged when an output voltage changes beyond a plurality of output voltage change range and beyond a plurality of output voltage change duration range, wherein the voltage detector VM transforms the abnormal state of the cable into a switch signal, and sends the switch signal to the signal transmission device.

5. The street light cable anti-theft system, as recited in claim 4, wherein the output voltage change ranges comprise a first output voltage change range, a second output voltage change range, a third output voltage change range and a fourth output voltage change range, wherein the first output voltage change range is an output voltage deviation produced when the street light EL is at a work condition, the second output voltage change range is an output voltage deviation produced when the street light EL is at a rest condition, the third output voltage change range is an output voltage deviation produced when the street light EL switches from the work condition to the rest condition, the fourth output voltage change range is an output voltage deviation produced when the street light EL switches from the rest condition to the work condition, wherein the output voltage change duration ranges comprise a first output voltage change duration range, a second output voltage change duration range, a third output voltage change duration range and a fourth output voltage change duration range, wherein the first output voltage change duration range is a length of time of said output voltage deviation produced when the street light EL is at a work condition, the second output voltage change duration range is a length of time of said output voltage deviation produced when the street light EL is at a rest condition, the third output voltage change duration range is a length of time of said output voltage deviation produced when the street light EL switches from the work condition to the rest condition, the fourth output voltage change duration range is a length of time of said output voltage deviation produced when the street light EL switches from the rest condition to the work condition, wherein the abnormal state of the cable is judged when an output voltage changes beyond the first output voltage change range and beyond the first output voltage change duration range or when the output voltage changes beyond the second output voltage change range and beyond the second output voltage change duration range or when the output voltage changes beyond the third output voltage change range and beyond the third output voltage change duration range or when the output voltage changes beyond the fourth output voltage change range and beyond the fourth output voltage change duration range, the normal state of the cable is judged when an output voltage doesn't change beyond the first output voltage change range or doesn't change beyond the first output voltage change duration range or when the output voltage doesn't change beyond the second output voltage change range or doesn't change beyond the second output voltage change duration range or when the output voltage doesn't change beyond the third output voltage change range or doesn't change beyond the third output voltage change duration range or when the output voltage doesn't change beyond the fourth output voltage change range or doesn't change beyond the fourth output voltage change duration range.

6. The street light cable anti-theft system, as recited in claim 4, wherein the signal transmission device is a Global System for Mobile communication (GSM) signal transmission device.

7. The street light cable anti-theft system, as recited in claim 5, wherein the signal transmission device is a Global System for Mobile communication (GSM) signal transmission device.

8. The street light cable anti-theft system, as recited in claim 4, wherein the switch controller is a time controller or street light terminal controller.

9. The street light cable anti-theft system, as recited in claim 5, wherein the switch controller is a time controller or street light terminal controller.

10. The street light cable anti-theft system, as recited in claim 6, wherein the switch controller is a time controller or street light terminal controller.

11. The street light cable anti-theft system, as recited in claim 7, wherein the switch controller is a time controller or street light terminal controller.

12. The street light cable anti-theft system, as recited in claim 4, wherein the front-end control device further comprises a first fuse for protecting the first battery pack when a short circuit occurs, and a positive electrode of the first battery pack is connected with the first fuse.

13. The street light cable anti-theft system, as recited in claim 5, wherein the front-end control device further comprises a first fuse for protecting the first battery pack when a short circuit occurs, and a positive electrode of the first battery pack is connected with the first fuse.

14. The street light cable anti-theft system, as recited in claim 4, wherein the signal control device further comprises a second fuse for protecting the second battery pack when a short circuit occurs, and a positive electrode of the second battery pack is connected with the second fuse.

15. The street light cable anti-theft system, as recited in claim 5, wherein the signal control device further comprises a second fuse for protecting the second battery pack when a short circuit occurs, and a positive electrode of the second battery pack is connected with the second fuse.

16. The street light cable anti-theft system, as recited in claim 4, wherein the street light is connected with the street light cable by a ballast.

17. The street light cable anti-theft system, as recited in claim 5, wherein the street light is connected with the street light cable by a ballast.
